(19) United States
(12) Patent Application Publication
(10) Pub. No.: US 2014/0030575 A1
(43) Pub. Date: Jan. 30, 2014

(54) Thermal Reservoir Using Phase-Change Material For Portable Applications

(71) Applicants: Gerald Ho Kim, Carlsbad, CA (US); Jay Eunjae Kim, Issaquah, WA (US)

(72) Inventors: Gerald Ho Kim, Carlsbad, CA (US); Jay Eunjae Kim, Issaquah, WA (US)

(21) Appl. No.: 13/951,388

(22) Filed: Jul. 25, 2013

Related U.S. Application Data
(60) Provisional application No. 61/676,592, filed on Jul. 27, 2012.

(51) Int. Cl. H05K 7/20

(52) U.S. Cl. CPC H05K 7/20436
USPC 429/120; 165/104.11; 165/104.21; 361/704

(57) ABSTRACT

An apparatus using a phase-change material for thermal management in portable applications is described. In one aspect, the apparatus includes a phase-change material, a thermal reservoir, and a heat transport element. The thermal reservoir has a cavity therein to contain the phase-change material in the cavity. The heat transport element is made of a thermally conductive material. A first portion of the heat transport element traverses through the thermal reservoir and in contact with the phase-change material. A second portion of the heat transport element extends outside the thermal reservoir. Accordingly, at least part of the thermal energy from an object in contact with the heat transport element can be transported to the phase-change material via the heat transport element and be absorbed by the phase-change material as latent heat. The phase-change material may release at least part of the absorbed thermal energy at a later time.

### CROSS REFERENCE TO RELATED PATENT APPLICATION

This is a non-provisional application based on and that claims the priority benefit of U.S. Patent Application 61/676,592 filed 27 Jul. 2012, which is incorporated by reference in its entirety.

### TECHNICAL FIELD

The present disclosure generally relates to the field of management of thermal energy and, more particularly, to the management of thermal energy with a phase-change material for portable applications.

### BACKGROUND

Compact heat-generating devices, such as laser diodes, light-emitting diodes (LEDs), vertical-cavity surface emitting lasers (VCSELs), imaging devices, integrated circuits including microprocessors, microwave chips and the like, generate thermal energy, or heat, when in operation. Regardless of which type of heat-generating device the case may be, heat generated by a compact heat-generating device needs to be removed or dissipated from the compact heat-generating device in order to achieve optimum performance of the compact heat-generating device and keep its temperature within a safe operating range. With the form factor of compact heat-generating devices (e.g., sensors or ASIC drivers in a telecom router, cellular phone tower, data communications server or mainframe computers) and the applications they are implemented in becoming ever smaller (e.g., the processor in a smartphone, a tablet computer or a notebook computer) resulting in high heat density, it is imperative to effectively dissipate the high-density heat generated in an area of small footprint to ensure safe and optimum operation of compact heat-generating devices operating under such conditions.

One issue with heat dissipation in portable/mobile applications is that, even when heat generated by a heat-generating device (e.g., the processor in a smartphone, a tablet computer or a notebook computer) is removed or otherwise transferred away from the heat-generating device, the heat more or less is transferred to other portion(s) of the portable apparatus in which the heat-generating device resides. This may not be desirable especially in portable/mobile applications. For instance, at least a portion of the heat generated by a microprocessor in a notebook computer is transferred to the casing of the notebook computer (e.g., a portion of the computer's casing closest to the microprocessor) making the casing warm or even hot to touch. As another example, some notebook computers may have a cooling fan installed therein to promote heat transfer by convection to cool off the microprocessor of the notebook computer. Still, warm air can be felt near a vent of the casing where the cooling fan blows hot air out of the casing, and the casing of the notebook computer may still be warm or even hot to touch. Consequently, user experience of such portable/mobile apparatus may be negatively impacted if not rendered dangerous.

### SUMMARY

Various embodiments of an apparatus for thermal management in portable applications using a phase-change material are provided.

According to one aspect, an apparatus for thermal management in portable applications may include a phase-change material, a thermal reservoir, and a heat transport element. The thermal reservoir may have a cavity therein that contains the phase-change material. The heat transport element may be made of a thermally conductive material. A first portion of the heat transport element may traverse through the thermal reservoir and may be in contact with the phase-change material. A second portion of the heat transport element may extend outside the thermal reservoir.

In at least some embodiments, the phase-change material may include a salt hydrate, an ionic liquid, paraffin, fatty acid, ester, an organic-organic compound, an organic-inorganic compound, or an inorganic-inorganic compound.

In at least some embodiments, the thermal reservoir may include at least one component made of a plastic material, a metallic material, a silicon-based material, carbon-fibers, or diamond.

In at least some embodiments, the heat transport element may include at least one component made of copper, silver, aluminum, zinc, silicon, carbon-fiber, nanowires, graphite, or diamond.

In at least some embodiments, a thermal conductivity of the heat transport element may be greater than or equal to a thermal conductivity of the thermal reservoir.

In at least some embodiments, the thermal reservoir may include a first half piece and a second half piece. The first half piece may have a first primary side and a second primary side opposite to the first primary side. The second primary side of the first half piece may include a recess. The second half piece may have a first primary side and a second primary side opposite to the first primary side. The second primary side of the second half piece may include a recess such that the cavity, configured to contain the phase-change material therein, is formed when the second primary side of the first half piece and the second primary side of the second half piece are mated together.

In at least some embodiments, the phase-change material may be in a liquid phase when filled into the cavity of the thermal reservoir. At least one of the first half piece and the second half piece may include one or more openings communicatively connecting the respective first primary side and the respective second primary side such that the phase-change material is filled into the cavity through the one or more openings.

In at least some embodiments, the first half piece and the second half piece may be bonded together.

In at least some embodiments, the heat transport element may include a sheet of mesh sandwiched between the first half piece and the second half piece of the thermal reservoir.

In at least some embodiments, the heat transport element may include a solid sheet sandwiched between the first half piece and the second half piece of the thermal reservoir.

In at least some embodiments, the apparatus may further include a middle piece sandwiched between the first half piece and the second half piece such that the recess on the second primary side of the first half piece, the recess on the second primary side of the second half piece, and the middle piece form the cavity.

In at least some embodiment, the heat transport element may include first and second sheets of mesh. The first sheet of mesh may be sandwiched between the first half piece and the middle piece. The second sheet of mesh may be sandwiched between the middle piece and the second half piece.

In at least some embodiments, the heat transport element may include first and second solid sheets. The first solid sheet may be sandwiched between the first half piece and the middle piece. The second solid sheet may be sandwiched between the middle piece and the second half piece.

According to one aspect, an apparatus for thermal management in portable applications may include a phase-change material, a thermal reservoir, a heat-generating device, and a heat transport element. The thermal reservoir may have a cavity therein that contains the phase-change material. The thermal reservoir may have a first end and a second end opposite to the first end. The heat-generating device may be coupled to and in contact with the first end of the thermal reservoir. The heat transport element may be made of a thermally and electrically conductive material. The heat transport element may traverse through the thermal reservoir and may be in contact with the phase-change material such that the heat transport element is connected to the heat-generating device at the first end of the thermal reservoir and extends outside the thermal reservoir at the second end of the thermal reservoir.

In at least some embodiments, the phase-change material may be electrically non-conductive.

In at least some embodiments, the phase-change material may include a salt hydrate, an ionic liquid, paraffin, fatty acid, ester, an organic-organic compound, an organic-inorganic compound, or an inorganic-inorganic compound.

In at least some embodiments, the thermal reservoir may include at least one component made of a plastic material, a metallic material, a silicon-based material, carbon-fibers, or diamond.

In at least some embodiments, the heat transport element may include at least one component made of copper, silver, aluminum, zinc, silicon, carbon-fiber, nanowires, or graphite.

In at least some embodiments, a thermal conductivity of the heat transport element may be greater than a thermal conductivity of the thermal reservoir.

In at least some embodiments, the heat transport element may be made of a first flexible material, and the thermal reservoir may be made of a second flexible material.

In at least some embodiments, the heat-generating device may include a light-emitting device, an imaging device, a combination thereof, or any electronic device which generates heat during operation.

In at least some embodiments, the apparatus may further include an electrical power source. In one embodiment, the electrical power source may include a battery device for the heat-generating device. The battery device may include: a second phase-change material, an electrolyte, or a combination thereof; a second thermal reservoir having a second cavity therein that contains the second phase-change material; and a second heat transport element made of a thermally conductive material, a first portion of the second heat transport element traversing through the second thermal reservoir and in contact with the second phase-change material, a second portion of the second heat transport element extending outside the second thermal reservoir. The second thermal reservoir may include: a first half piece having a first primary side and a second primary side opposite to the first primary side, the second primary side of the first half piece includes a recess; a second half piece having a first primary side and a second primary side opposite to the first primary side, the second primary side of the second half piece includes a recess such that the second cavity, configured to contain the phase-change material therein, is formed when the second primary side of the first half piece and the second primary side of the second half piece are mated together; and a middle piece sandwiched between the first half piece and the second half piece such that the recess on the second primary side of the first half piece, the recess on the second primary side of the second half piece, and the middle piece form the second cavity. The second heat transport element may include: a first solid sheet or sheet of mesh sandwiched between the first half piece and the middle piece; and a second solid sheet or sheet of mesh sandwiched between the middle piece and the second half piece.

In at least some embodiments, the heat transport element may include two wires electrically connecting the heat-generating device and the electrical power source such that electrical power is provided to the heat-generating device from the electrical power source via the heat transport element.

This summary is provided to introduce concepts relating to an apparatus that uses a phase-change material for thermal management in portable applications. Some embodiments of the apparatus are further described below in the detailed description. This summary is not intended to identify essential features of the claimed subject matter, nor is it intended for use in determining the scope of the claimed subject matter.

### BRIEF DESCRIPTION OF THE DRAWINGS

The accompanying drawings are included to provide a further understanding of the disclosure, and are incorporated in and constitute a part of the present disclosure. The drawings illustrate embodiments of the disclosure and, together with the description, serve to explain the principles of the disclosure. It is appreciable that the drawings are not necessarily in scale as some components may be shown to be out of proportion than the size in actual implementation in order to clearly illustrate the concept of the present disclosure.

FIG. 1 is a perspective view of an apparatus for thermal management in portable applications using a phase-change material in accordance with an embodiment of the present disclosure.

FIG. 2 is a cross-sectional view of the apparatus of FIG. 1 in accordance with an embodiment of the present disclosure.

FIG. 3 is a perspective view of an apparatus for thermal management in portable applications using a phase-change material in accordance with another embodiment of the present disclosure.

FIG. 4 is a cross-sectional view of the apparatus of FIG. 3 in accordance with an embodiment of the present disclosure.

FIG. 5 is a perspective view of an apparatus for thermal management in portable applications using a phase-change material in accordance with still another embodiment of the present disclosure.

FIG. 6 is a perspective view of an apparatus for thermal management in portable applications using a phase-change material in accordance with yet another embodiment of the present disclosure.

FIG. 7 is a perspective view of an apparatus for thermal management in portable applications using a phase-change material and with a battery device in accordance with an embodiment of the present disclosure.

FIG. 8 is a perspective view of an apparatus for thermal management in portable applications using a phase-change material and with a battery device in accordance with another embodiment of the present disclosure.

### DETAILED DESCRIPTION OF PREFERRED EMBODIMENTS

### Overview

The present disclosure describes embodiments of an apparatus for thermal energy in portable applications using a phase-change material. Various embodiments of the disclosed apparatus are capable of absorbing and storing thermal energy generated by a heat-generating device near or in contact with the apparatus. More specifically, various embodiments of the disclosed apparatus are capable of absorbing and storing thermal energy as latent heat in that the apparatus absorbs and stores up to a certain amount of thermal energy without a change in temperature. This feature advantageously allows thermal energy to be transferred away from the heat-generating device, thereby optimizing the performance and useful life of the heat-generating device, while providing enhanced user experience in that the portable/mobile apparatus in which the heat-generating device resides is not warm or hot to touch. When the heat-generating device is not in operation or in a low-power mode, e.g., sleep mode or standby mode during which the heat-generating device is generating little or no heat, thermal energy stored in the apparatus may be slowly released out of the apparatus and to a heat sink, in addition to or including releasing to the casing of the portable/mobile apparatus. As thermal energy is slowly released from the apparatus to the heat sink and eventually to the casing of the portable/mobile apparatus, the portable/mobile apparatus is barely warm to touch, if at all.

### First Illustrative Embodiment

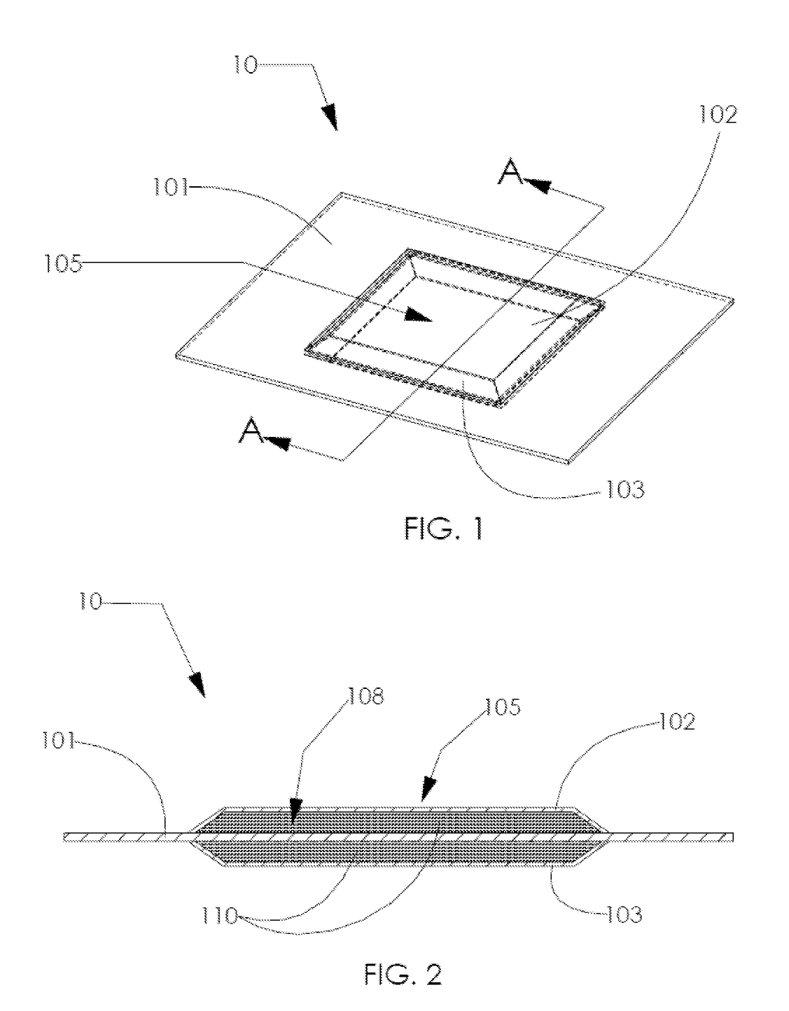

FIGS. 1-2 illustrate various views of a thermal management apparatus 10. The apparatus 10 includes a phase-change material 110, a thermal reservoir 105, and a heat transport element 101. The thermal reservoir 105 has a cavity 108 therein that contains the phase-change material 110. The heat transport element 101 is made of a thermally conductive material. A first portion of the heat transport element 101 (e.g., a central portion thereof) traverses through the thermal reservoir 105 and is in contact with the phase-change material 110. A second portion of the heat transport element 101 (e.g., a peripheral portion or one or more distal ends thereof) extends outside the thermal reservoir 105. The heat transport element 101 may be in the form of a sheet, as shown in FIGS. 1-2, or any other suitable form.

In at least some embodiments, the phase-change material 110 includes a salt hydrate, an ionic liquid, paraffin, fatty acid, ester, an organic-organic compound, an organic-inorganic compound, or an inorganic-inorganic compound.

In at least some embodiments, the thermal reservoir 105 includes at least one component made of a plastic material, a metallic material, a ceramic material, a silicon-based material (e.g., single crystal, or monocrystalline, silicon or poly crystal silicon), or diamond.

In at least some embodiments, the heat transport element 101 includes at least one component made of copper, silver, aluminum, zinc, ceramic, silicon, carbon-fiber, nanowires, graphite, or diamond.

In at least some embodiments, a thermal conductivity of the heat transport element 101 is greater than a thermal conductivity of the thermal reservoir 105. Alternatively, the thermal conductivity of the heat transport element 101 is approximately equal to the thermal conductivity of the thermal reservoir 105. In other words, the heat transport element 101 conducts heat at least as well as or better than the thermal reservoir 105 does.

In at least some embodiments, the thermal reservoir 105 includes a first half piece 102 and a second half piece 103. The first half piece 102 has a first primary side and a second primary side opposite to the first primary side. The second primary side of the first half piece 102 includes a recess. Similarly, the second half piece 103 has a first primary side and a second primary side opposite to the first primary side. The second primary side of the second half piece 103 includes a recess. Accordingly, the cavity 108, which is configured to contain the phase-change material 110 therein, is formed when the second primary side of the first half piece 102 and the second primary side of the second half piece 103 are mated together.

In at least some embodiments, the phase-change material 110 is in a liquid phase when filled into the cavity 108 of the thermal reservoir 105. Either or both of the first half piece 102 and the second half piece 103 include one or more openings communicatively connecting the respective first primary side and the respective second primary side. The one or more openings on the first half piece 102 and/or the second half piece 103 allow the phase-change material 110 to be filled into the cavity 108 through the one or more openings.

After the phase-change material 110 is filled into the cavity 108 of the thermal reservoir 105, the one or more openings on the first half piece 102 and/or the second half piece 103 are plugged, e.g., by epoxy or any suitable method and material, to prevent the phase-change material 110 from leaking out of the thermal reservoir 105.

In at least some embodiments, the first half piece 102 and the second half piece 103 are bonded together.

In at least some embodiments, the heat transport element 101 is a sheet of mesh sandwiched between the first half piece 102 and the second half piece 103 of the thermal reservoir 105.

In at least some embodiments, the heat transport element 101 is a solid sheet sandwiched between the first half piece 102 and the second half piece 103 of the thermal reservoir 105.

The phase-change material 110 partially or fully fills the cavity 108 of the thermal reservoir 105. Accordingly, the phase-change material 110 physically contacts and surrounds the first portion of the heat transport element 101, which traverses through the cavity 108. In various implementations, the second portion of the heat transport element 101 may be in physical contact with or near one or more heat-generating devices (e.g., a microprocessor, a light-emitting device such as a laser diode or an LED, an imaging device, etc.), such that at least part of the thermal energy from the one or more heat-generating devices is transferred to the second portion of the heat transport element 101 by conduction (e.g., via physical contact), convection (e.g., via air), and/or radiation. Subsequently, the phase-change material 110 absorbs at least some of such thermal energy from the heat transport element 101. As the phase-change material 110 can absorb the thermal energy as latent heat, temperature of the phase-change material 110 as well as the thermal reservoir 105 would not change until at least up to a certain amount of thermal energy has been absorbed by the phase-change material 110. Advantageously, as some or all of the thermal energy released from the one or more heat-generating devices is absorbed by the phase-change material 110 in the thermal reservoir 105, the casing of a portable device in which the apparatus 10 resides would not be hot or even warm to touch under normal operating conditions.

### Second Illustrative Embodiment

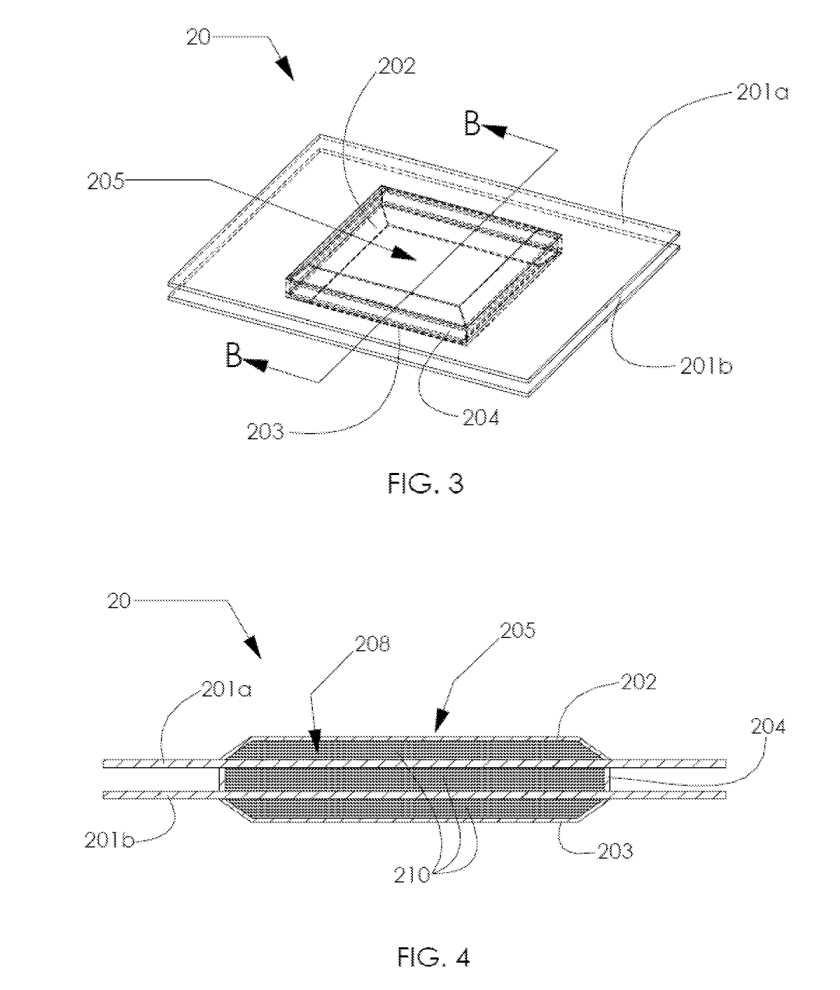

FIGS. 3-4 illustrate various views of a thermal management apparatus 20. The apparatus 20 includes a phase-change material 210, a thermal reservoir 205, and a heat transport element 201. The thermal reservoir 205 has a cavity 208 therein that contains the phase-change material 210. The heat transport element 201, made of a thermally conductive material, has first piece 201a and second piece 201b. A first portion of the heat transport element 201 (e.g., a central portion thereof) traverses through the thermal reservoir 205 and is in contact with the phase-change material 210. A second portion of the heat transport element 201 (e.g., a peripheral or one or more distal ends thereof) extends outside the thermal reservoir 205. Each of the first piece 201a and the second piece 201b of the heat transport element 201 may be in the form of a sheet, as shown in FIGS. 3-4, or any other suitable form.

In at least some embodiments, the phase-change material 210 includes a salt hydrate, an ionic liquid, paraffin, fatty acid, ester, an organic-organic compound, an organic-inorganic compound, or an inorganic-inorganic compound.

In at least some embodiments, the thermal reservoir 205 includes at least one component made of a plastic material, a metallic material, a ceramic material, a silicon-based material (e.g., single crystal, or monocrystalline, silicon or poly crystal silicon), or diamond.

In at least some embodiments, the heat transport element 201 includes at least one component made of copper, silver, aluminum, zinc, ceramic, silicon, carbon-fiber, nanowires, graphite, or diamond.

In at least some embodiments, a thermal conductivity of the heat transport element 201 is greater than a thermal conductivity of the thermal reservoir 205. Alternatively, the thermal conductivity of the heat transport element 201 is approximately equal to the thermal conductivity of the thermal reservoir 205. In other words, the heat transport element 201 conducts heat at least as well as or better than the thermal reservoir 205 does.

In at least some embodiments, the thermal reservoir 205 includes a first half piece 202, a second half piece 203, and a middle piece 204. The first half piece 202 has a first primary side and a second primary side opposite to the first primary side. The second primary side of the first half piece 202 includes a recess. Similarly, the second half piece 203 has a first primary side and a second primary side opposite to the first primary side. The second primary side of the second half piece 203 includes a recess. The middle piece 204 is sandwiched between the first half piece 202 and the second half piece 203 such that the recess on the second primary side of the first half piece 202, the recess on the second primary side of the second half piece 203, and the middle piece 204 form the cavity 208.

In at least some embodiments, the phase-change material 210 is in a liquid phase when filled into the cavity 208 of the thermal reservoir 205. One or more of the first half piece 202, the second half piece 203, and the middle piece 204 include one or more openings communicatively connecting the respective first primary side and the respective second primary side. The one or more openings on the first half piece 202, the second half piece 203, and/or the middle piece 204 allow the phase-change material 210 to be filled into the cavity 208 through the one or more openings.

After the phase-change material 210 is filled into the cavity 208 of the thermal reservoir 205, the one or more openings on the first half piece 202, the second half piece 203, and/or the middle piece 204 are plugged, e.g., by epoxy or any suitable method and material, to prevent the phase-change material 210 from leaking out of the thermal reservoir 205.

In at least some embodiments, the first half piece 202, the middle piece 204, and the second half piece 203 are bonded together.

In at least some embodiment, the first piece 201a of the heat transport element 201 is sandwiched between the first half piece 202 and the middle piece 204. The second piece 201b of the heat transport element 201 is sandwiched between the middle piece 204 and the second half piece 203.

In at least some embodiments, the first piece 201a and the second piece 201b of the heat transport element 201 are sheets of mesh. Alternatively, the first piece 201a and the second piece 201b of the heat transport element 201 are solid sheets.

The phase-change material 210 partially or fully fills the cavity 208 of the thermal reservoir 205. Accordingly, the phase-change material 210 physically contacts and surrounds the first portion of the heat transport element 201, which traverses through the cavity 208. In various implementations, the second portion of the heat transport element 201 may be in physical contact with or near one or more heat-generating devices (e.g., a microprocessor, a light-emitting device such as a laser diode or an LED, an imaging device, etc.), such that at least part of the thermal energy from the one or more heat-generating devices is transferred to the second portion of the heat transport element 201 by conduction (e.g., via physical contact), convection (e.g., via air), and/or radiation. Subsequently, the phase-change material 210 absorbs at least some of such thermal energy from the heat transport element 201. As the phase-change material 210 can absorb the thermal energy as latent heat, temperature of the phase-change material 210 as well as the thermal reservoir 105 would not change at least up to a certain amount of thermal energy absorbed by the phase-change material 210. Advantageously, as some or all of the thermal energy released from the one or more heat-generating devices is absorbed by the phase-change material 210 in the thermal reservoir 205, the casing of a portable device in which the apparatus 20 resides would not be hot or even warm to touch under normal operating conditions.

### Third Illustrative Embodiment

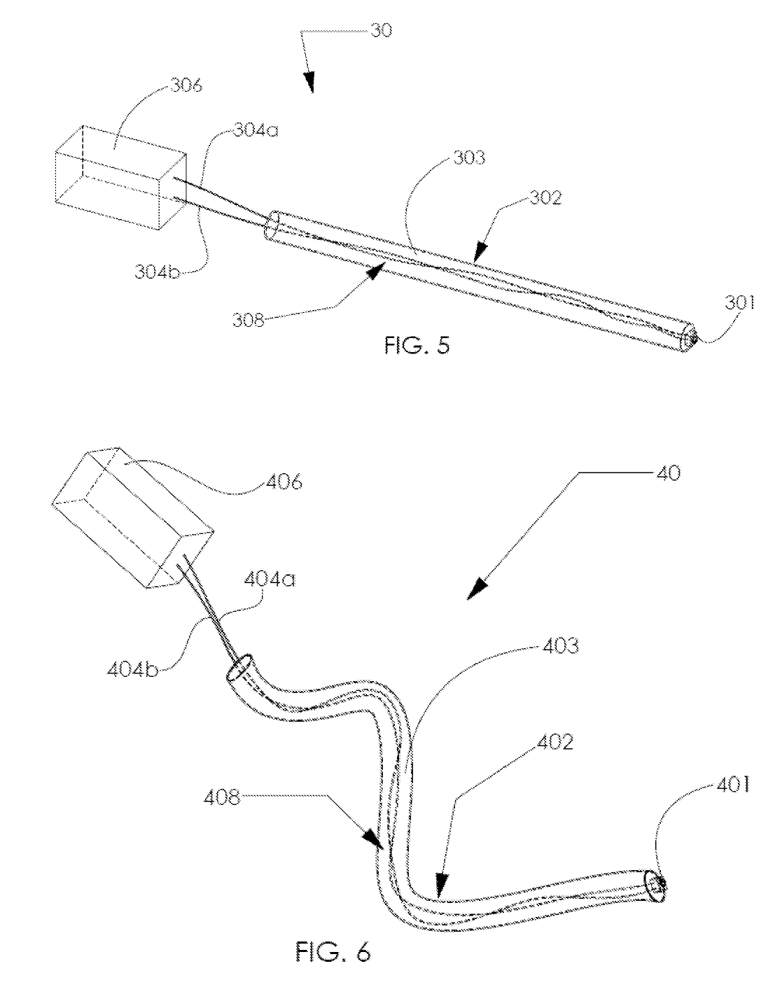

FIG. 5 illustrates a perspective view of a thermal management apparatus 30. The apparatus 30 includes a phase-change material 303, a thermal reservoir 302, a heat-generating device 301, and a heat transport element 304. The thermal reservoir 302 has a cavity 308 therein that contains the phase-change material 303. The thermal reservoir 302 has a generally cylindrical shape and has a first end and a second end opposite to the first end. The heat-generating device 301 is coupled to and in contact with the first end of the thermal reservoir 302. In one embodiment, the heat transport element 304 is made of a thermally and electrically conductive material. Alternatively, the heat transport element 304 is made of a thermally conductive but electrically non-conductive material. The heat transport element 304 traverses through the thermal reservoir 302 and is in contact with the phase-change material 303. More specifically, the heat transport element 304 is connected to the heat-generating device 301 at the first end of the thermal reservoir 302, traverses through the thermal reservoir 302 inside the thermal reservoir 302, and extends outside the thermal reservoir 302 at the second end of the thermal reservoir 302. Thus, the heat transport element 304 is in direct contact with the phase-change material 303 which is contained in the thermal reservoir 302.

In at least some embodiments, the phase-change material 303 is electrically non-conductive.

In at least some embodiments, the phase-change material 303 includes a salt hydrate, an ionic liquid, paraffin, fatty acid, ester, an organic-organic compound, an organic-inorganic compound, or an inorganic-inorganic compound.

In at least some embodiments, the thermal reservoir 302 includes at least one component made of a plastic material, a metallic material, a ceramic material, a silicon-based material (e.g., single crystal, or monocrystalline, silicon or poly crystal silicon), carbon-fibers, or diamond.

In at least some embodiments, the heat transport element 304 includes at least one component made of copper, silver, aluminum, zinc, ceramic, silicon, carbon-fiber, nanowires, or graphite.

In at least some embodiments, a thermal conductivity of the heat transport element 304 is greater than a thermal conductivity of the thermal reservoir 302. Alternatively, the thermal conductivity of the heat transport element 304 is approximately equal to the thermal conductivity of the thermal reservoir 302. In other words, the heat transport element 304 conducts heat at least as well as or better than the thermal reservoir 302 does.

In at least some embodiments, the thermal reservoir 302 is made of a rigid material. The heat transport element 304 is made of a rigid material or a flexible material.

In at least some embodiments, the heat-generating device 301 includes a light-emitting device, an imaging device, a combination thereof, or any electronic device which generates heat during operation.

In at least some embodiments, the apparatus 30 further includes an electrical power source 306. For example, the electrical power source 306 may be a battery.

In at least some embodiments, the heat transport element 304 include two wires 304a, 304b that electrically connect the heat-generating device 301 and the electrical power source 306 such that electrical power is provided to the heat-generating device 301 from the electrical power source 306 via the heat transport element 304.

### Fourth Illustrative Embodiment

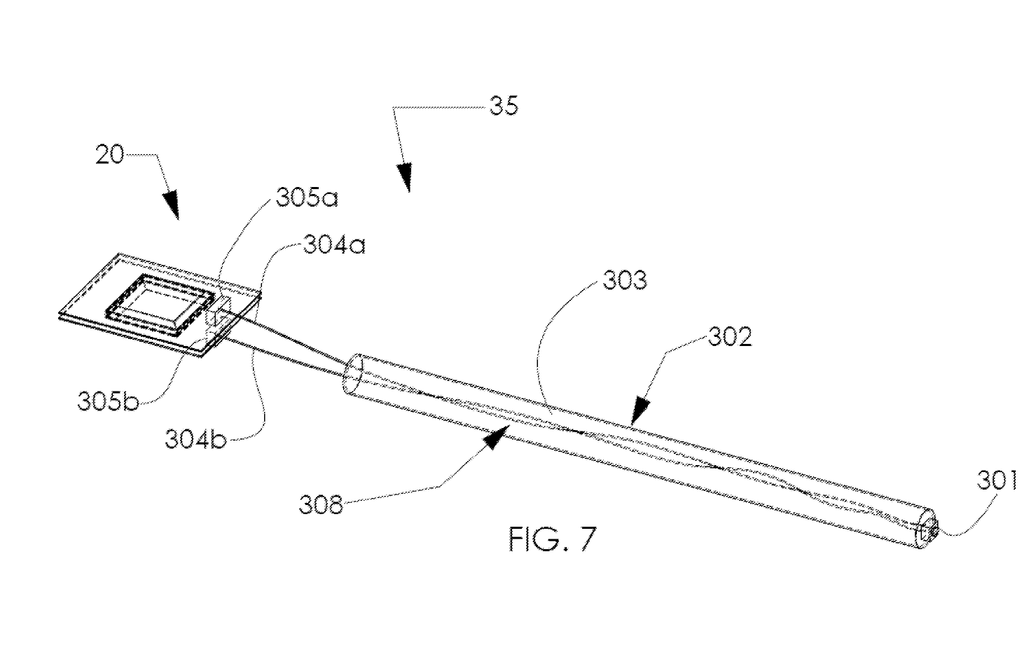

FIG. 6 illustrates a perspective view of a thermal management apparatus 40. The apparatus 40 includes a phase-change material 403, a thermal reservoir 402, a heat-generating device 401, and a heat transport element 404. The thermal reservoir 402 has a cavity 408 therein that contains the phase-change material 403. The thermal reservoir 402 has a generally cylindrical shape and has a first end and a second end opposite to the first end. The heat-generating device 401 is coupled to and in contact with the first end of the thermal reservoir 402. In one embodiment, the thermal reservoir 402 of the apparatus 40 is flexible and thus can be bent. In one embodiment, the heat transport element 404 is made of a thermally and electrically conductive material. Alternatively, the heat transport element 404 is made of a thermally conductive but electrically non-conductive material. The heat transport element 404 traverses through the thermal reservoir 402 and is in contact with the phase-change material 403. More specifically, the heat transport element 404 is connected to the heat-generating device 401 at the first end of the thermal reservoir 402, traverses through the thermal reservoir 402 inside the thermal reservoir 402, and extends outside the thermal reservoir 402 at the second end of the thermal reservoir 402. Thus, the heat transport element 404 is in direct contact with the phase-change material 403 which is contained in the thermal reservoir 402.

In at least some embodiments, the phase-change material 403 is electrically non-conductive.

In at least some embodiments, the phase-change material 403 includes a salt hydrate, an ionic liquid, paraffin, fatty acid, ester, an organic-organic compound, an organic-inorganic compound, or an inorganic-inorganic compound.

In at least some embodiments, the thermal reservoir 402 includes at least one component made of a plastic material, a metallic material, a ceramic material, a silicon-based material (e.g., single crystal, or monocrystalline, silicon or poly crystal silicon), carbon-fibers, or diamond.

In at least some embodiments, the heat transport element 404 includes at least one component made of copper, silver, aluminum, zinc, ceramic, silicon, carbon-fiber, nanowires, or graphite.

In at least some embodiments, a thermal conductivity of the heat transport element 404 is greater than a thermal conductivity of the thermal reservoir 402. Alternatively, the thermal conductivity of the heat transport element 404 is approximately equal to the thermal conductivity of the thermal reservoir 402. In other words, the heat transport element 404 conducts heat at least as well as or better than the thermal reservoir 402 does.

In at least some embodiments, the thermal reservoir 402 is made of a flexible material. The heat transport element 404 is made of a flexible material.

In at least some embodiments, the heat-generating device 401 includes a light-emitting device, an imaging device, a combination thereof, or any electronic device which generates heat during operation.

In at least some embodiments, the apparatus 40 further includes an electrical power source 406. For example, the electrical power source 406 may be a battery.

In at least some embodiments, the heat transport element 404 include two wires 404a, 404b that electrically connect the heat-generating device 401 and the electrical power source 406 such that electrical power is provided to the heat-generating device 401 from the electrical power source 406 via the heat transport element 404.

### Fifth Illustrative Embodiment

FIG. 7 illustrates a perspective view of a thermal management apparatus 35. The apparatus 35 includes a phase-change material 303, a thermal reservoir 302, a heat-generating device 301, and a heat transport element 304. The thermal reservoir 302 has a cavity 308 therein that contains the phase-change material 303. Given that certain components of the apparatus 35 are identical to those of the apparatus 30, detailed description of the thermal management apparatus 35 below focuses on the difference.

The apparatus 35 includes the thermal management apparatus 20 of FIGS. 3-4 functioning as a battery device that uses a phase-change material to hold battery charge for longer time. A typical battery is constructed with anode, cathode and electrolyte, and these elements are placed in a metal container that holds all these elements. The application of thermal reservoir is to use the silicon container that is illustrated in FIGS. 3-4, which has two electrodes 305a and 305b (each coupled to a respective one of the first piece 201a and the second piece 201b of the heat transport element 201 as well as the wires 304a and 304b, respectively) that can act as anode and cathode. The electrolyte is also made by mixing the phase-change material 210 with normal electrolyte. Alternatively, a suitably-formulated phase-change matter can be used to function as an electrolyte solution.

In one embodiment, one of the electrodes 305a and 305b that functions as the anode is made of graphite, and the other one of the electrodes 305a and 305b that functions as the cathode is made of a layered oxide (e.g., lithium cobalt oxide), a polyanion (e.g., lithium iron phosphate), or a spinel (e.g., lithium manganese oxide).

In one embodiment, the electrolyte is a mixture of organic carbonates, e.g., ethylene carbonate or diethyl carbonate containing complexes of lithium ions. The non-aqueous electrolyte generally uses non-coordinating anion salts such as lithium hexafluorophosphate (LiPF₆), lithium hexafluoroarsenate monohydrate (LiAsF₆), lithium perchlorate (liClO₄), lithium tetrafluoroborate (liBF₄), and lithium triflate (LiCF₃SO₃).

The thermal management apparatus 20 functioning as a battery device with a thermal reservoir can be charged at an elevated temperature where the phase-change material is in a liquid phase to act as an electrolyte or allow the normal electrolyte to carry ions so that it will function as a normal battery. When the battery is fully charged, the elevated temperature can be lowered to freeze the phase-change material. In this case, all charges build up at the anode (e.g., one of the electrodes 305a and 305b) and no ion can flow without melting the phase-change material. This battery device is very useful in storing the battery charge for a long time without any internal discharge over time. Also, this battery device can be used as a heat-dumping reservoir in portable devices such as mobile phones, laptops, flat-panel computers, tablets, and any compact electronic devices.

### Sixth Illustrative Embodiment

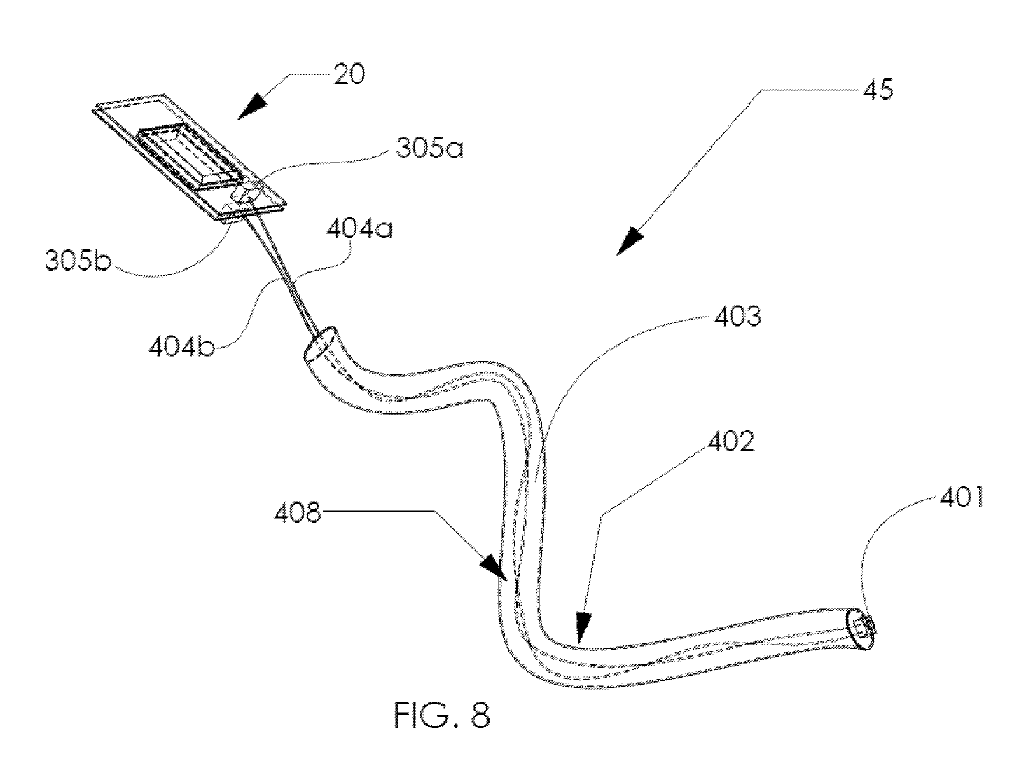

FIG. 8 illustrates a perspective view of a thermal management apparatus 45. The apparatus 45 includes a phase-change material 403, a thermal reservoir 402, a heat-generating device 401, and a heat transport element 404. The thermal reservoir 402 has a cavity 408 therein that contains the phase-change material 403. Given that certain components of the apparatus 45 are identical to those of the apparatus 40, detailed description of the thermal management apparatus 45 below focuses on the difference.

The apparatus 45 includes the thermal management apparatus 20 of FIGS. 3-4 functioning as a battery device that uses a phase-change material to hold battery charge for longer time. A typical battery is constructed with anode, cathode and electrolyte, and these elements are placed in a metal container that holds all these elements. The application of thermal reservoir is to use the silicon container that is illustrated in FIGS. 3-4, which has two electrodes 405a and 405b (each coupled to a respective one of the first piece 201a and the second piece 201b of the heat transport element 201 as well as the wires 404a and 404b, respectively) that can act as anode and cathode. The electrolyte is also made by mixing the phase-change material 210 with normal electrolyte. Alternatively, a suitably-formulated phase-change matter can be used to function as an electrolyte solution.

In one embodiment, one of the electrodes 405a and 405b that functions as the anode is made of graphite, and the other one of the electrodes 405a and 405b that functions as the cathode is made of a layered oxide (e.g., lithium cobalt oxide), a polyanion (e.g., lithium iron phosphate), or a spinel (e.g., lithium manganese oxide).

In one embodiment, the electrolyte is a mixture of organic carbonates, e.g., ethylene carbonate or diethyl carbonate containing complexes of lithium ions. The non-aqueous electrolyte generally uses non-coordinating anion salts such as lithium hexafluorophosphate (LiPF₆), lithium hexafluoroarsenate monohydrate (LiAsF₆), lithium perchlorate (liClO₄), lithium tetrafluoroborate (liBF₄), and lithium triflate (LiCF₃SO₃).

The thermal management apparatus 20 functioning as a battery device with a thermal reservoir can be charged at an elevated temperature where the phase-change material is in a liquid phase to act as an electrolyte or allow the normal electrolyte to carry ions so that it will function as a normal battery. When the battery is fully charged, the elevated temperature can be lowered to freeze the phase-change material. In this case, all charges build up at the anode (e.g., one of the electrodes 405a and 405b) and no ion can flow without melting the phase-change material. This battery device is very useful in storing the battery charge for a long time without any internal discharge over time. Also, this battery device can be used as a heat-dumping reservoir in portable devices such as mobile phones, laptops, flat-panel computers, tablets, and any compact electronic devices.

In each of the examples shown in FIGS. 7 and 8, the thermal management apparatus 20 functions as a battery and, in some implementations, a phase-change material based battery. A portable electronic apparatus utilizing an embodiment of the battery would dump most, if not all, heat generated by the electronics therein into the battery, thus melting the phase-change material in the battery to release the ion flow of the phase-change material. Advantageously, this improves current flow within and amongst the electronic components of the portable electronic apparatus. The inventive battery design of the present disclosure would increase the battery's performance as the battery warms up. The battery performance can be improved or maintained as heat gets dumped into the battery which is filled with phase-change material or a mixture of phase-change material and electrolyte. In contrast, most conventional portable electronic apparatuses tend to suffer from relatively lower current flow as the battery of the conventional portable electronic apparatus warms up. Normally the battery in a conventional portable electronic apparatus will die fast or shut itself off under prolonged operation under high temperature, but the performance of the battery of the present disclosure can be maintained as the battery heats up.

### Exemplary Portable Applications

The above-described thermal management apparatus may be used in a portable electronics apparatus for thermal energy storage and management. For example, the above-described thermal management apparatus may be used in a portable electronics apparatus such as a tablet computer (e.g., iPad by Apple of Cupertino, Calif.), hand-held mobile communication device (e.g., iPhone by Apple of Cupertino, Calif.), notebook/laptop computer, or any suitable hand-held portable device.

Accordingly, a portable electronics apparatus may include a thermal energy storage apparatus and an electronics device disposed on or inside the thermal energy storage apparatus such that at least a portion of thermal energy generated by the electronics device is transferred to and absorbed by the thermal energy storage apparatus. The thermal energy storage apparatus may include a non-metal-based container configured to receive the electronics device thereon or therein. The thermal energy storage apparatus may further include a phase-change material contained in the non-metal-based container and configured to absorb at least a portion of heat from the electronics device through the non-metal-based container. The electronics device may include a heat-generating device and a substrate on which the heat-generating device is disposed.

### CONCLUSION

The above-described techniques pertain to thermal management using a phase-change material in a thermal reservoir for portable applications. Although the techniques have been described in language specific to certain applications, it is to be understood that the appended claims are not necessarily limited to the specific features or applications described herein. Rather, the specific features and applications are disclosed as exemplary forms of implementing such techniques.

What is claimed is:

1. An apparatus, comprising:
a phase-change material;
a thermal reservoir having a cavity therein that contains the phase-change material; and
a heat transport element made of a thermally conductive material, a first portion of the heat transport element traversing through the thermal reservoir and in contact with the phase-change material, a second portion of the heat transport element extending outside the thermal reservoir.

2. The apparatus of claim 1, wherein the phase-change material comprises a salt hydrate, an ionic liquid, paraffin, fatty acid, ester, an organic-organic compound, an organic-inorganic compound, or an inorganic-inorganic compound.

3. The apparatus of claim 1, wherein the thermal reservoir comprises at least one component made of a silicon-based material.

4. The apparatus of claim 1, wherein the heat transport element comprises at least one component made of copper, silver, aluminum, zinc, silicon, carbon-fiber, nanowires, graphite, or diamond.

5. The apparatus of claim 1, wherein a thermal conductivity of the heat transport element is greater than a thermal conductivity of the thermal reservoir.

6. The apparatus of claim 1, wherein the thermal reservoir comprises:
a first half piece having a first primary side and a second primary side opposite to the first primary side, the second primary side of the first half piece includes a recess; and
a second half piece having a first primary side and a second primary side opposite to the first primary side, the second primary side of the second half piece includes a recess such that the cavity, configured to contain the phase-change material therein, is formed when the second primary side of the first half piece and the second primary side of the second half piece are mated together.

7. The apparatus of claim 6, wherein the phase-change material is in a liquid phase when filled into the cavity of the thermal reservoir, and wherein at least one of the first half piece and the second half piece includes one or more openings communicatively connecting the respective first primary side and the respective second primary side such that the phase-change material is filled into the cavity through the one or more openings.

8. The apparatus of claim 6, wherein the heat transport element comprises a sheet of mesh sandwiched between the first half piece and the second half piece of the thermal reservoir.

9. The apparatus of claim 6, wherein the heat transport element comprises a solid sheet sandwiched between the first half piece and the second half piece of the thermal reservoir.

10. The apparatus of claim 6, further comprising:
a middle piece sandwiched between the first half piece and the second half piece such that the recess on the second primary side of the first half piece, the recess on the second primary side of the second half piece, and the middle piece form the cavity.

11. The apparatus of claim 10, wherein the heat transport element comprises:
a first sheet of mesh sandwiched between the first half piece and the middle piece; and
a second sheet of mesh sandwiched between the middle piece and the second half piece.

12. The apparatus of claim 10, wherein the heat transport element comprises:
a first solid sheet sandwiched between the first half piece and the middle piece; and
a second solid sheet sandwiched between the middle piece and the second half piece.

13. An apparatus, comprising:
a phase-change material;
a thermal reservoir having a cavity therein that contains the phase-change material, the thermal reservoir having a first end and a second end opposite to the first end;
a heat-generating device that is coupled to and in contact with the first end of the thermal reservoir; and
a heat transport element made of a thermally and electrically conductive material, the heat transport element traversing through the thermal reservoir and in contact with the phase-change material such that the heat transport element is connected to the heat-generating device at the first end of the thermal reservoir and extends outside the thermal reservoir at the second end of the thermal reservoir.

14. The apparatus of claim 13, wherein the phase-change material is electrically non-conductive.

15. The apparatus of claim 13, wherein the phase-change material comprises a salt hydrate, an ionic liquid, paraffin, fatty acid, ester, an organic-organic compound, an organic-inorganic compound, or an inorganic-inorganic compound.

16. The apparatus of claim 13, wherein the thermal reservoir comprises at least one component made of a silicon-based material.

17. The apparatus of claim 13, wherein the heat transport element comprises at least one component made of copper, silver, aluminum, zinc, silicon, carbon-fiber, nanowires, or graphite.

18. The apparatus of claim 13, wherein a thermal conductivity of the heat transport element is greater than a thermal conductivity of the thermal reservoir.

19. The apparatus of claim 13, wherein the heat-generating device comprises a light-emitting device, an imaging device, a combination thereof, or any electronic device which generates heat during operation.

20. The apparatus of claim 13, further comprising:
a battery device which functions an electrical power source for the heat-generating device, the battery device comprising:
a second phase-change material, an electrolyte, or a combination thereof;
a second thermal reservoir having a second cavity therein that contains the second phase-change material; and
a second heat transport element made of a thermally conductive material, a first portion of the second heat transport element traversing through the second thermal reservoir and in contact with the second phase-change material, a second portion of the second heat transport element extending outside the second thermal reservoir, wherein the second thermal reservoir comprises:
a first half piece having a first primary side and a second primary side opposite to the first primary side, the second primary side of the first half piece includes a recess;
a second half piece having a first primary side and a second primary side opposite to the first primary side, the second primary side of the second half piece includes a recess such that the second cavity, configured to contain the phase-change material therein, is formed when the second primary side of the first half piece and the second primary side of the second half piece are mated together; and
a middle piece sandwiched between the first half piece and the second half piece such that the recess on the second primary side of the first half piece, the recess on the second primary side of the second half piece, and the middle piece form the second cavity, and wherein the second heat transport element comprises:
a first solid sheet or sheet of mesh sandwiched between the first half piece and the middle piece; and
a second solid sheet or sheet of mesh sandwiched between the middle piece and the second half piece.
